(19) United States
(12) Patent Application Publication
(10) Pub. No.: US 2015/0102832 A1
(43) Pub. Date: Apr. 16, 2015

(54) CARRIER DISASSEMBLING APPARATUS, ELECTRONIC DEVICE HOUSING APPARATUS, ELECTRONIC DEVICE RETRIEVING APPARATUS, AND ELECTRONIC DEVICE TESTING APPARATUS

(71) Applicant: ADVANTEST CORPORATION, Tokyo (JP)

(72) Inventor: Yoshinari Kogure, Saitama (JP)

(73) Assignee: ADVANTEST CORPORATION, Tokyo (JP)

(21) Appl. No.: 14/400,994

(22) PCT Filed: May 21, 2013
(86) PCT No.: PCT/JP2013/064079

§ 371 Date: Nov. 13, 2014

(30) Foreign Application Priority Data
May 31, 2012 (JP) 2012-125262

(51) Int. Cl. G01R 31/28; G01R 1/04

(52) U.S. Cl. CPC G01R 31/2893; G01R 1/0408
USPC 324/757.01; 29/705

(57) ABSTRACT

A carrier disassembling apparatus which disassembles a test carrier including a base member and a cover member coming into close contact with each other, includes: a first reversing arm which sucks and holds the cover member; and a disassembly table which sucks and holds the base member. The first reversing arm can approach and separate from the disassembly table. The first reversing arm includes a first contract surface which comes into contact with the cover member. The first contract surface includes a protrusion which protrudes toward the cover member.

### TECHNICAL FIELD

The present invention relates to a carrier disassembling apparatus which disassembles a test carrier on which an electronic device, such as a die chip having an integrated circuit formed therein, is temporarily mounted, and an electronic device housing apparatus, an electronic device retrieving apparatus, and an electronic device testing apparatus including the carrier disassembling apparatus.

For the designated countries which permit the incorporation by reference, the contents described and/or illustrated in Japanese Patent Application No. 2012-125262 filed on May 31, 2012 will be incorporated herein by reference as a part of the description and/or drawings of the present application.

### BACKGROUND ART

A technique has been known which tests a device using a test package formed by sucking gas between a first board and a second board to seal a device between the first board and the second board (for example, see Patent Document 1).

### CITATION LIST

### Patent Document

Patent Document 1: WO 2010/109739 A

### DISCLOSURE OF THE INVENTION

### Problem to be Solved by the Invention

In the above-mentioned technique, when the device is retrieved from the test carrier, it is difficult to detach the second board from the first board since the first and second boards come into close contact with each other.

An object of the invention is to provide a carrier disassembling apparatus which can improve the disassembly workability of a test carrier, and an electronic device housing apparatus, an electronic device retrieving apparatus, and an electronic device testing apparatus including the carrier disassembling apparatus.

### Means for Solving Problem

[1] A carrier disassembling apparatus according to the present invention is a carrier disassembling apparatus which disassembles a test carrier including a first member and a second member which come into contact with each other, the carrier disassembling apparatus comprises: a first holding means which sucks and holds the first member; and a second holding means which sucks and holds the second member, wherein one of the first holding means or the second holding means can relatively approach and separate from the other of the second holding means or the first holding means, the first holding means includes a first contract surface which comes into contact with the first member, and the first contract surface includes a protrusion which protrudes toward the first member.

[2] In the above-mentioned invention, the first member may include: a first frame member which has a frame shape with a first opening; and a first film member which is stuck to the first frame member, the first holding means may include: a first suction portion which is inserted into the first opening and sucks the first film member; and a second suction portion which sucks the first frame member, the first suction portion may include the first contract surface which comes into contact with the first film member, and a first suction port may be opened in the first contract surface.

[3] In the above-mentioned invention, the first suction portion may include a first side surface which intersects the first contract surface, and a second suction port may be opened in the first side surface.

[4] In the above-mentioned invention, the second suction portion may include a first endless sealing member which comes into contact with the first frame member.

[5] In the above-mentioned invention, the first film member may have a self-adhesive property.

[6] In the above-mentioned invention, the first film member may be made of silicone rubber.

[7] In the above-mentioned invention, the second member may include: a second frame member which has a frame shape with a second opening; and a second film member which is stuck to the second frame member, the second holding means may include: a third suction portion which is inserted into the second opening and sucks the second film member; and a fourth suction portion which sucks the second frame member, the third suction portion may include a second contract surface which comes into contact with the second film member, and a third suction port may be opened in the second contract surface.

[8] In the above-mentioned invention, the third suction portion may include a second side surface which intersects the second contract surface, and a fourth suction port may be opened in the second side surface.

[9] In the above-mentioned invention, the fourth suction portion may include a second endless sealing member which comes into contact with the second frame member.

[10] An electronic device housing apparatus according to the invention is an electronic device housing apparatus which interposes an electronic device between a first member and a second member to house the electronic device in a test carrier, the electronic device housing apparatus comprising: the above-mentioned first carrier disassembly means which disassembles an empty test carrier; and a first carrier assembly means which interposes the electronic device between the first member and the second member and sticks the first member and the second member.

[11] An electronic device retrieving apparatus according to the invention is an electronic device retrieving apparatus which retrieves an electronic device between a first member and a second member of a test carrier, the electronic device retrieving apparatus comprising: the above-mentioned second carrier disassembly means which disassembles the test carrier; and a second carrier assembly means which sticks the disassembled first and second members to reassemble the test carrier, wherein the second carrier disassembling means further includes an retrieving means which retrieves the electronic device from the disassembled test carrier.

[12] An electronic device testing apparatus according to the invention is an electronic device testing apparatus which houses an electronic device in a test carrier and tests the electronic device, the electronic device testing apparatus comprising: the above-mentioned electronic device housing unit, a test execution unit which tests the electronic device housed in the test carrier, and the above-mentioned electronic device retrieving unit.

### Effect of the Invention

According to the invention, since the contract surface of the first holding means in the carrier disassembling apparatus has the protrusion formed thereon, it is easy to detach the first member from the second member and the disassembly workability of the test carrier is improved.

### BRIEF DESCRIPTION OF DRAWINGS

FIG. 1 is a flowchart illustrating a portion of a device manufacturing process in an embodiment of the invention;

FIG. 2 is an exploded perspective view illustrating a test carrier in the embodiment of the invention;

FIG. 3 is a cross-sectional view illustrating the test carrier in the embodiment of the invention;

FIG. 4 is an exploded cross-sectional view illustrating the test carrier in the embodiment of the invention;

FIG. 5 is an enlarged view illustrating a V portion of FIG. 4;

FIG. 6 is an exploded cross-sectional view illustrating a modification of the test carrier in the embodiment of the invention;

FIG. 7 is an exploded perspective view illustrating another modification of the test carrier in the embodiment of the invention;

FIG. 8 is a cross-sectional view illustrating a modification of a cover member in the embodiment of the invention;

FIG. 9 is a cross-sectional view illustrating a modification of a base member in the embodiment of the invention;

FIG. 10 is a perspective view illustrating an electronic device testing apparatus in the embodiment of the invention;

FIG. 11 is a block diagram illustrating the outline of the electronic device testing apparatus in the embodiment of the invention;

FIG. 12 is a plan view illustrating the structure of an housing unit in the embodiment of the invention;

FIG. 13 is a schematic cross-sectional view taken along the line XIII-XIII of FIG. 12;

FIG. 14 is an enlarged view illustrating an XIV of FIG. 13;

FIG. 15 is a plan view illustrating a holding portion of a first reversing arm in the embodiment of the invention;

FIGS. 16(a) to 16(c) are diagrams illustrating an empty test carrier disassembly operation of the housing unit in the embodiment of the invention;

FIG. 17 is a plan view illustrating the structure of a test unit in the embodiment of the invention;

FIG. 18 is a cross-sectional view illustrating the internal structure of a test cell in the embodiment of the invention;

FIG. 19 is a cross-sectional view illustrating another example of the test cell in the embodiment of the invention;

FIG. 20 is a schematic cross-sectional view illustrating the structure of an retrieving unit in the embodiment of the invention; and

FIG. 21 is an enlarged view illustrating an XXI portion of FIG. 20.

### MODE(S) FOR CARRYING OUT THE INVENTION

Hereinafter, an embodiment of the invention will be described with reference to the drawings.

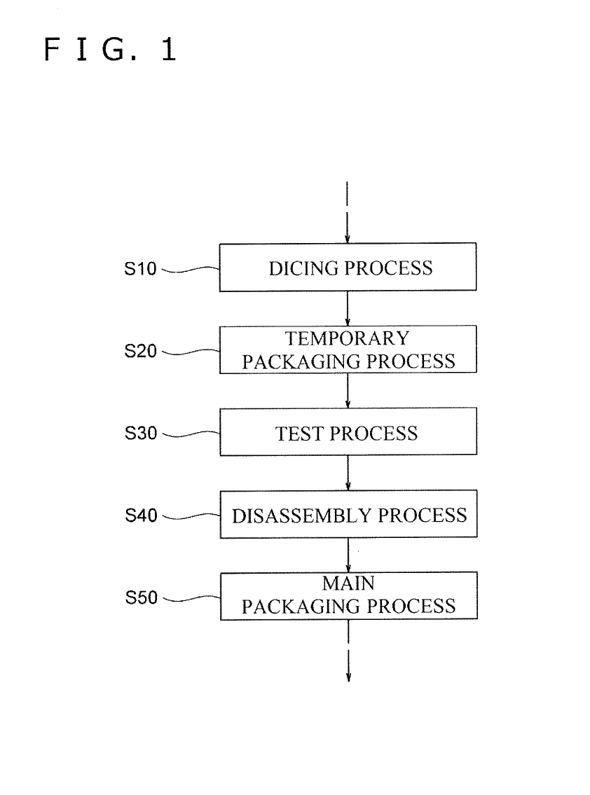

FIG. 1 is a flowchart illustrating a portion of a device manufacturing process in the present embodiment.

In the present embodiment, an electronic circuit which is incorporated into a die 90 is tested (Steps S20 to S40) after a semiconductor wafer is diced (after Step S10 in FIG. 1) and before final packaging is performed (before Step S50).

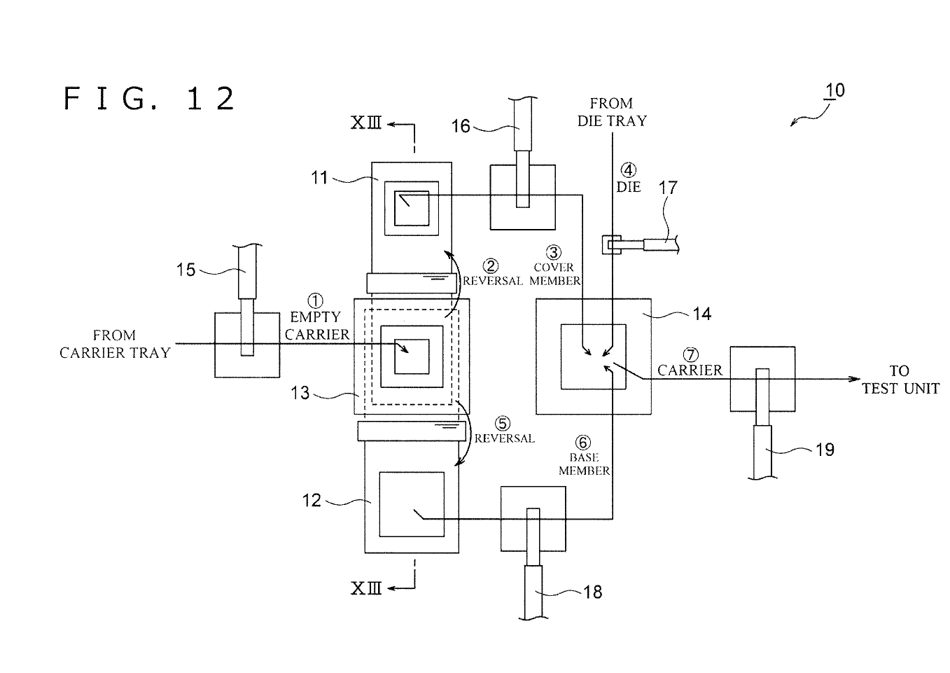

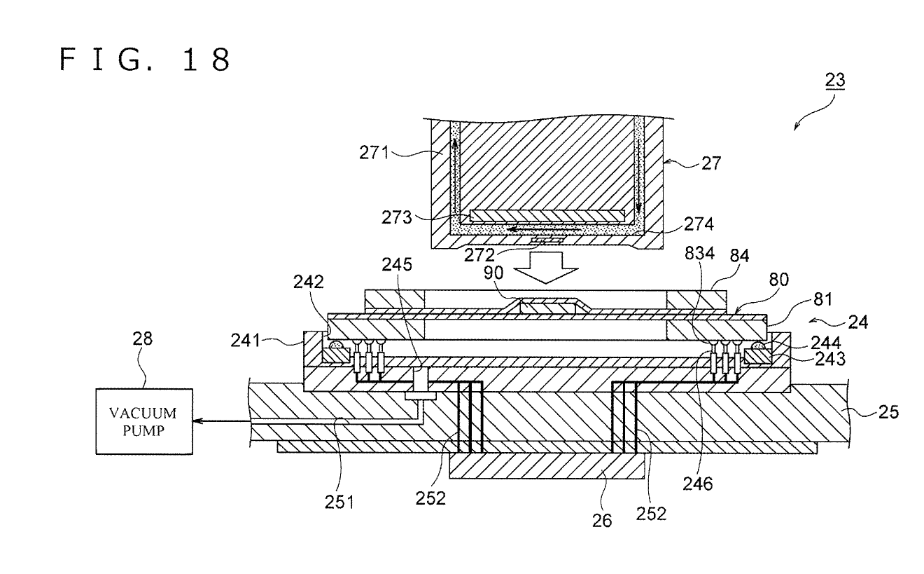

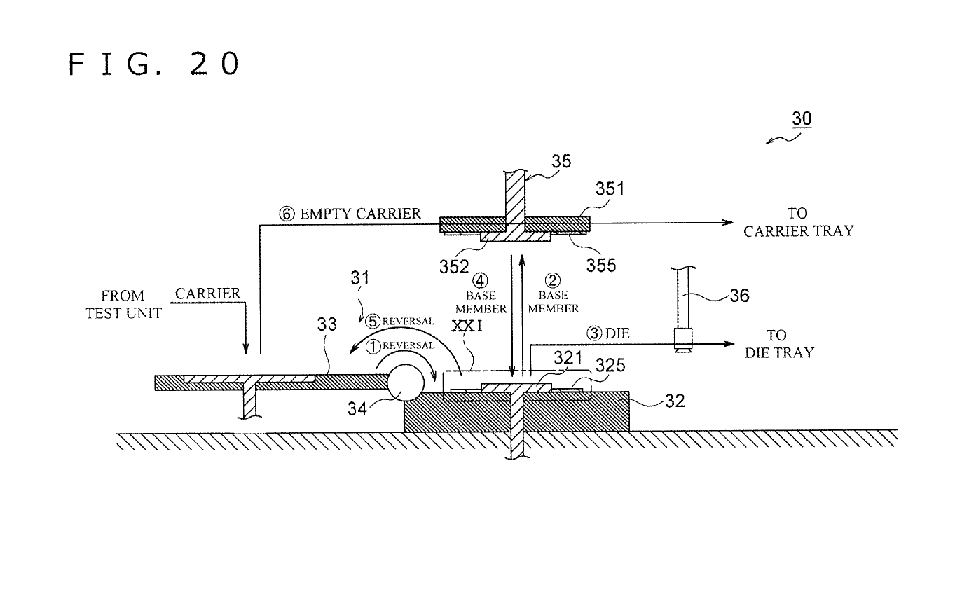

In the present embodiment, first, the die 90 is temporarily mounted on a test carrier 80 by an housing unit 10 (see FIG. 12) (Step S20). Then, the die 90 is electrically connected to a test circuit 26 of a test unit 20 (see FIG. 18) through the test carrier 80, and an electronic circuit formed in the die 90 is tested (Step S30). After the test ends, the die 90 is taken out of the test carrier 80 by a retrieving unit 30 (see FIG. 20) (Step S40), and main packaging is performed on the die 90. In this way, a device is completed as a final product.

At that time, in the present embodiment, the test carrier 80 from which the tested die 90 has been retrieved is reassembled in the retrieving unit 30. Then, the empty test carrier 80 is returned from the retrieving unit 30 to the housing unit 10. In this way, the test carrier 80 is recycled.

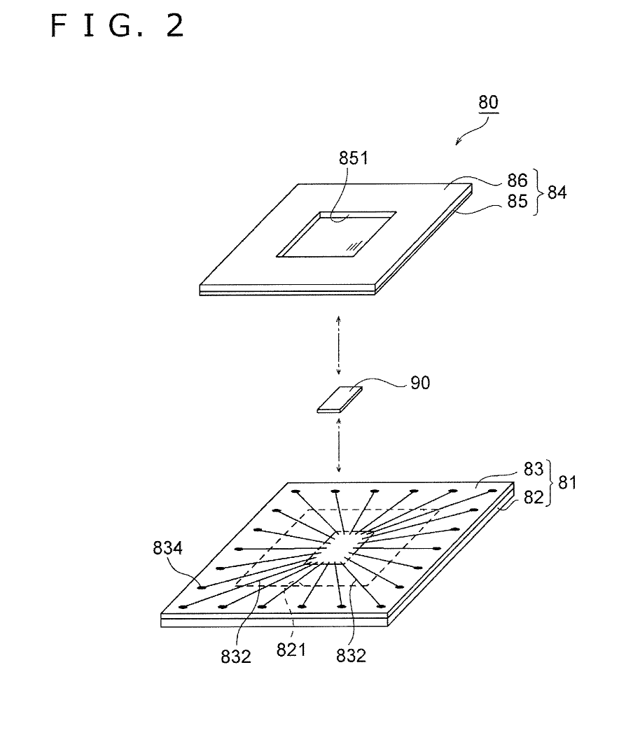

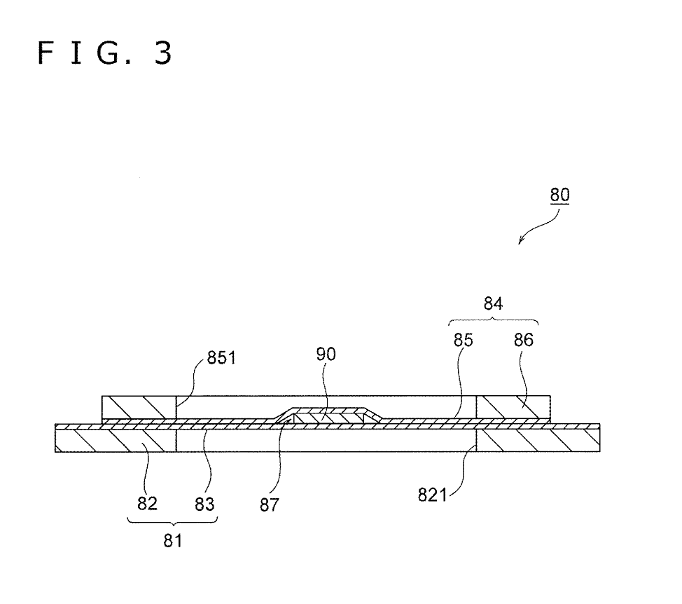

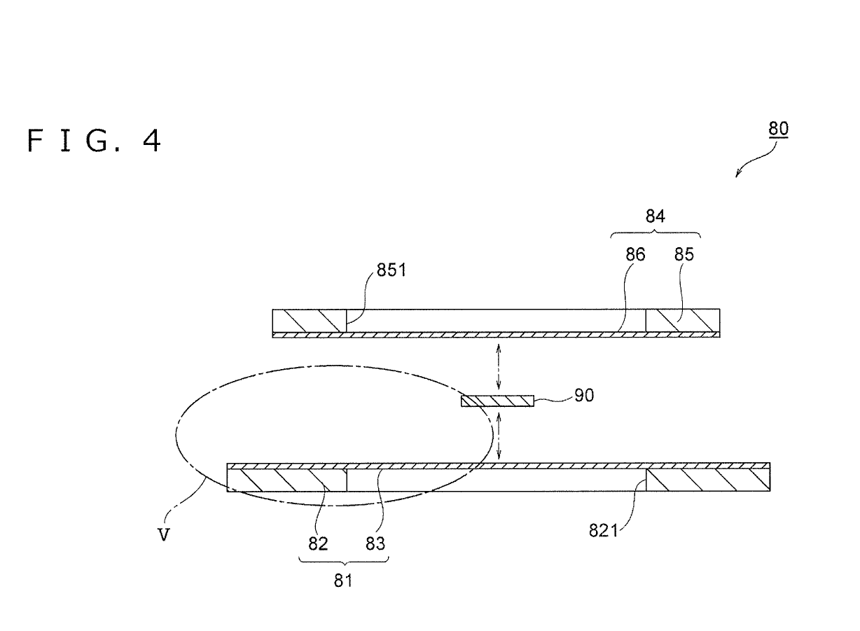

First, the structure of the test carrier 80 on which the die 90 is temporarily mounted (temporarily packaged) in the present embodiment will be described with reference to FIGS. 2 to 9.

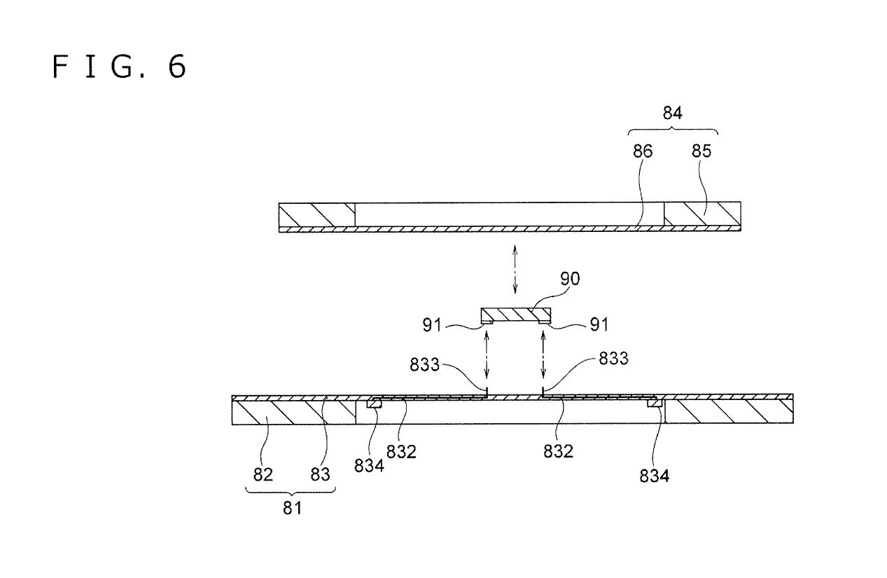

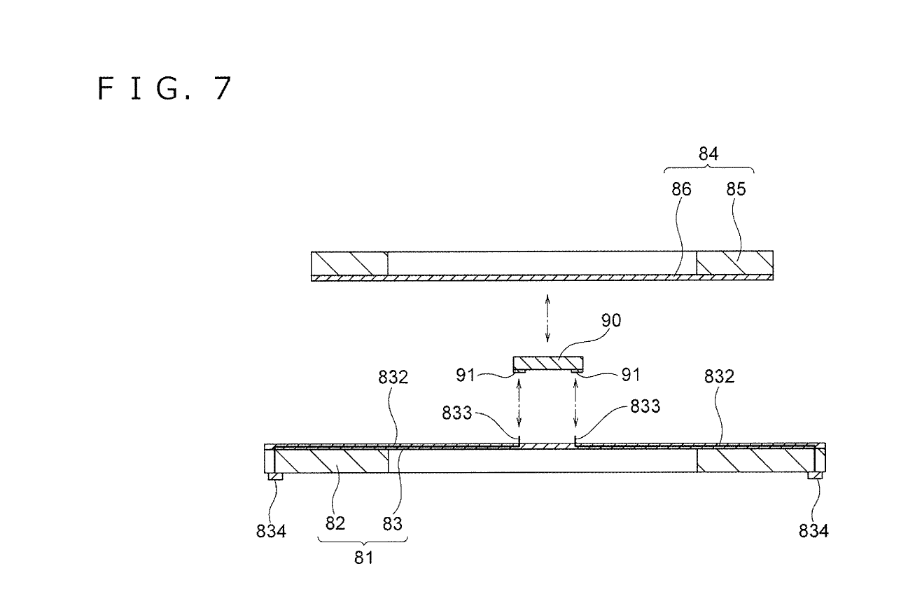

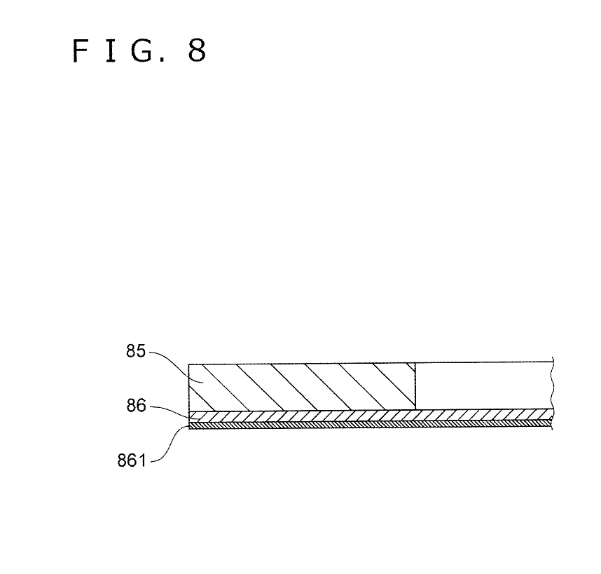

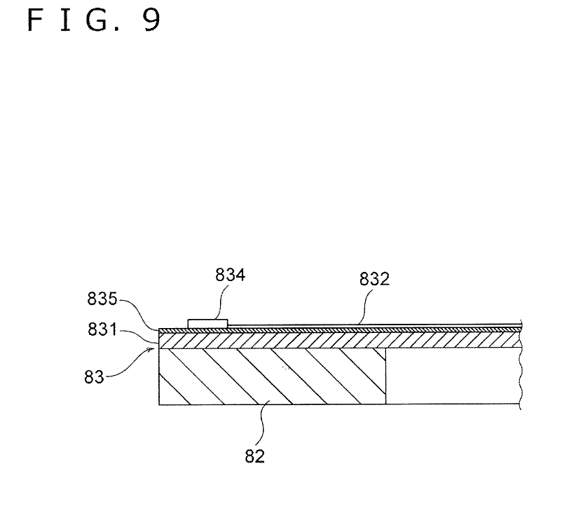

FIGS. 2 to 5 are diagrams illustrating the test carrier in the present embodiment. FIGS. 6 and 7 are diagrams illustrating modifications of the test carrier in the present embodiment. FIG. 8 is a diagram illustrating a modification of a cover member in the present embodiment. FIG. 9 is a diagram illustrating a modification of a base member in the present embodiment.

As illustrated in FIGS. 2 to 4, the test carrier 80 in the present embodiment includes: a base member 81 on which the die 90 is placed; and a cover member 84 which overlaps the base member 81 so as to cover the die 90. The die 90 is interposed between the base member 81 and the cover member 84, and the test carrier 80 holds the die 90. The die 90 in the present embodiment corresponds to an example of an electronic device in the present invention.

The base member 81 includes a base frame 82 and a base film 83. The base member 81 in the present embodiment corresponds to an example of a second member in the present invention.

The base frame 82 is a rigid plate with a substantially rectangular ring shape (frame shape) which has high rigidity (has higher rigidity than at least the base film 83) and has an opening 821 formed at the center thereof. Examples of the material forming the base frame 82 can include a polyimide resin, a polyamide-imide resin, a glass epoxy resin, ceramics, and glass. The shape of the base frame 82 is not particularly limited. For example, the base frame 82 may have a circular ring shape.

The base film 83 is a flexible film and is stuck to the entire surface of the base frame 82 including the central opening 821 by an adhesive (not illustrated). As such, in the present embodiment, since the base film 83 with flexibility is stuck to the base frame 82 with high rigidity, the handling ability of the base member 81 is improved.

The base frame 82 may be omitted and the base member may include only the base film 83. Alternatively, the base film 83 may be omitted and a rigid printed wiring board in which a wiring pattern is formed on a base frame without the opening 821 may be used as the base member.

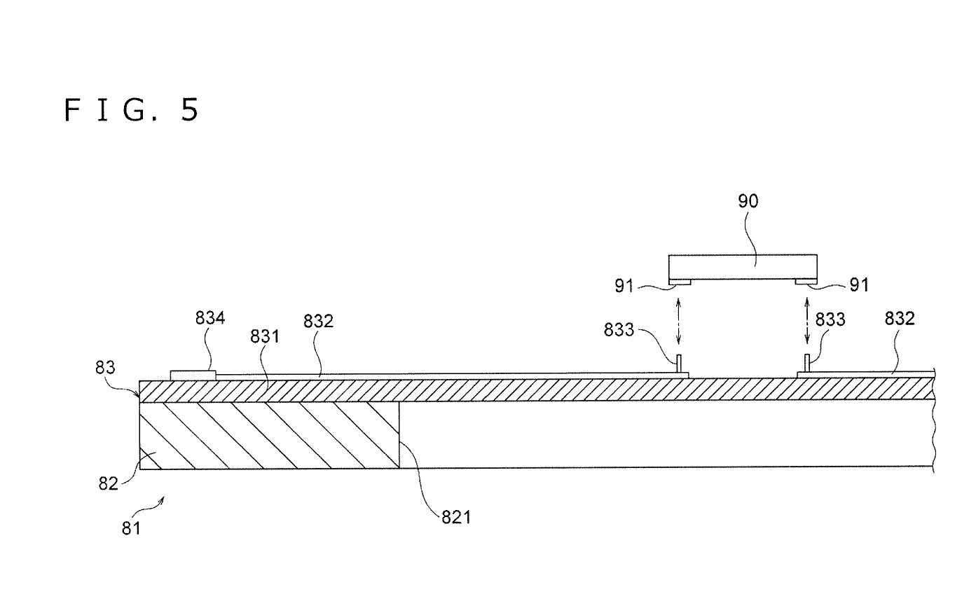

As illustrated in FIG. 5, the base film 83 includes: a film body 831; and wiring patterns 832 each of which is formed on the surface of the film body 831. The film body 831 is, for example, a polyimide film. Each of the wiring patterns 832 is formed by, for example, etching a copper film laminated on the film body 831. In addition, a cover layer, which is, for example, a polyimide film, may be further formed on the film body 831 to protect the wiring pattern 832, or a so-called multi-layer flexible printed wiring board may be used as the base film.

As illustrated in FIG. 5, a bump 833 (contact) is vertically provided at one end of the wiring pattern 832 so as to come into electrical contact with an electrode pad 91 of the die 90. The bump 833 is made of, for example, copper (Cu) or nickel (Ni) and is formed on the end of the wiring pattern 832 by, for example, a semi-additive method.

An external terminal 834 is formed at the other end of the wiring pattern 832. When the electronic circuit formed on the die 90 is tested, a contactor (see FIG. 18) of the test unit 20 comes into electrical contact with the external terminal 834, and the die 90 is electrically connected to a test circuit 26 of the test unit 20 through the test carrier 80.

The wiring pattern 832 is not limited to the above-mentioned structure. Although not particularly illustrated in the drawings, for example, a portion of the wiring pattern 832 may be formed in real time on the surface of the base film 83 by an ink-jet printing method. Alternatively, the entire wiring pattern 832 may be formed by the ink-jet printing method.

FIG. 5 illustrates only two electrode pads 91. However, in practice, a plurality of electrode pads 91 are formed on the die 90. In addition, a plurality of bumps 833 are formed on the base film 83 so as to correspond to the electrode pads 91.

The position of the external terminal 834 is not limited to the above-mentioned position. For example, as illustrated in FIG. 6, the external terminal 834 may be formed on the lower surface of the base film 83. Alternatively, as illustrated in FIG. 7, the external terminal 834 may be formed on the lower surface of the base frame 82. In the example illustrated in FIG. 7, a through hole and a wiring pattern is formed in the base frame 82, in addition to the base film 83, to electrically connect the bump 823 and the external terminal 824.

Although not particularly illustrated in the drawings, the wiring pattern or the external terminal may be formed on a cover film 86 in addition to the base film 83, or the external terminal may be formed on a cover frame 85.

As illustrated in FIGS. 2 to 4, the cover member 84 includes the cover frame 85 and the cover film 86. The cover member 84 in the present embodiment corresponds to an example of a first member in the invention.

The cover frame 85 is a rigid plate with a substantially rectangular ring shape (frame shape) which has high rigidity (has higher rigidity than at least the base film 83) and has an opening 851 formed at the center thereof. The cover frame 85 is made of, for example, glass, a polyimide resin, a polyamide-imide resin, a glass epoxy resin, or ceramics. The shape of the cover frame 85 is not particularly limited. For example, the cover frame 85 may have a circular ring shape.

The cover film 86 in the present embodiment is made of an elastic material which has a lower Young's modulus (lower hardness) than that forming the base film 83 and has a self-adhesive property (stickiness). The cover film 86 is more flexible than the base film 83. Examples of the material forming the cover film 86 include silicone rubber and polyurethane. The term “self-adhesive property” means a property that an object can be stuck without using an adhesive or bond. In the present embodiment, the base member 81 and the cover member 84 are integrated by the self-adhesive property of the cover film 86, instead of the reduced pressure method according to the related art.

The cover film 86 may be made of a material which has a lower Young's modulus than that forming the base film 83 and, for example, silicone rubber may be coated on the surface of the cover film 86 so as to form a self-adhesive layer 861, as illustrated in FIG. 8, thereby giving the self-adhesive property to the cover film 86.

Alternatively, the cover film 86 may be made of a material which has a lower Young's modulus than that forming the base film 83 and, for example, silicone rubber may be coated on the surface of the base film 83 so as to form a self-adhesive layer 835, as illustrated in FIG. 9, thereby giving the self-adhesive property to the base film 83. Both the cover film and the base film may have the self-adhesive property.

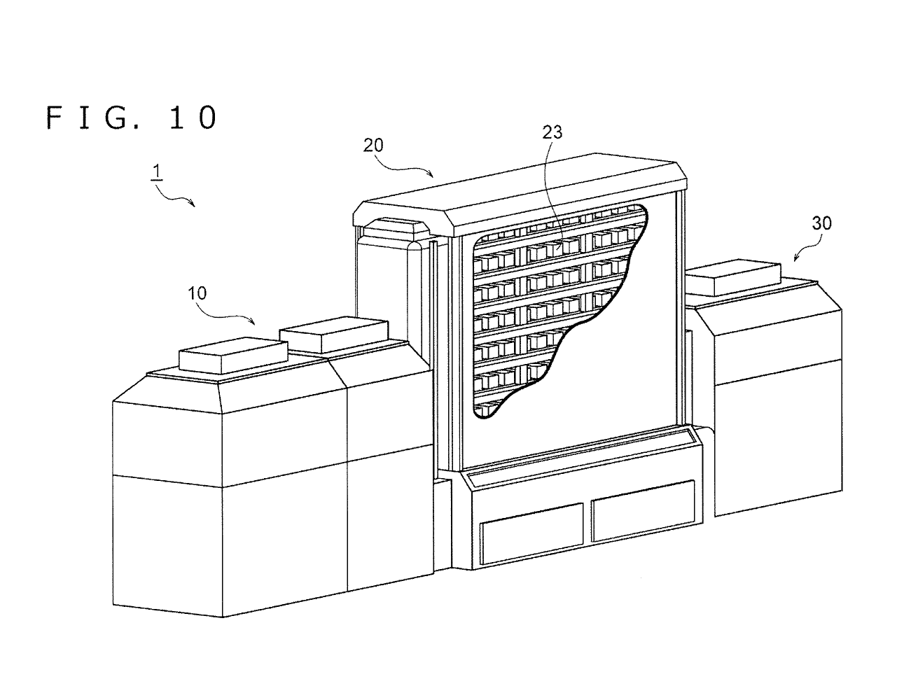

Next, the structure of an electronic device testing apparatus 1 which tests the die 90 using the test carrier 80 will be described with reference to FIGS. 10 to 21.

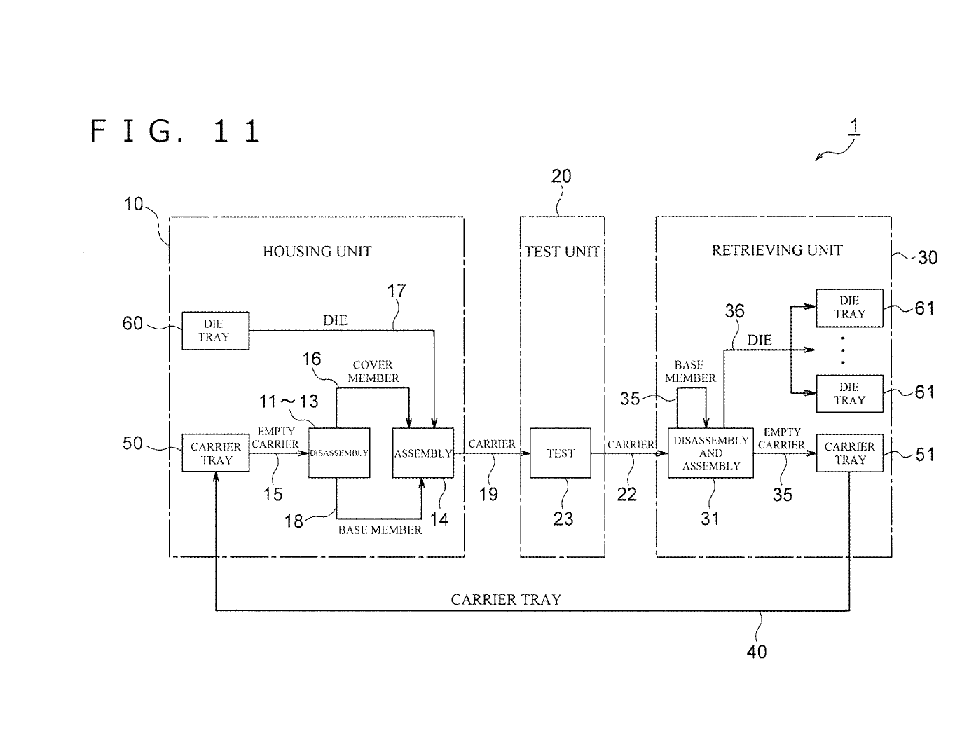

FIG. 10 is a perspective view illustrating the electronic device testing apparatus in the present embodiment. FIG. 11 is a block diagram illustrating the outline of the electronic device testing apparatus.

As illustrated in FIGS. 10 and 11, the electronic device testing apparatus 1 in the present embodiment includes: the housing unit 10 which houses (inserts) the die 90 into the empty test carrier 80; the test unit 20 which tests the die 90 housed in the test carrier 80; and the retrieving unit 30 which retrieves (extracts) the tested die 90 from the test carrier 80 and classifies the die 90 on the basis of the test result.

In the present embodiment, the housing unit 10 can disassemble the empty test carrier 80 before the die 90 is housed in the test carrier 80. The retrieving unit 30 can reassemble the empty test carrier 80 after the die 90 is retrieved from the test carrier 80. As illustrated in FIG. 11, the electronic device testing apparatus 1 in the present embodiment includes a return unit 40 which returns the empty test carrier 80 from the retrieving unit 30 to the housing unit 10 and can recycle the test carrier 80. For example, an automatic conveyance apparatus, such as an automatic guided vehicle (AGV) or an automatic conveyor, can be used as the return unit 40.

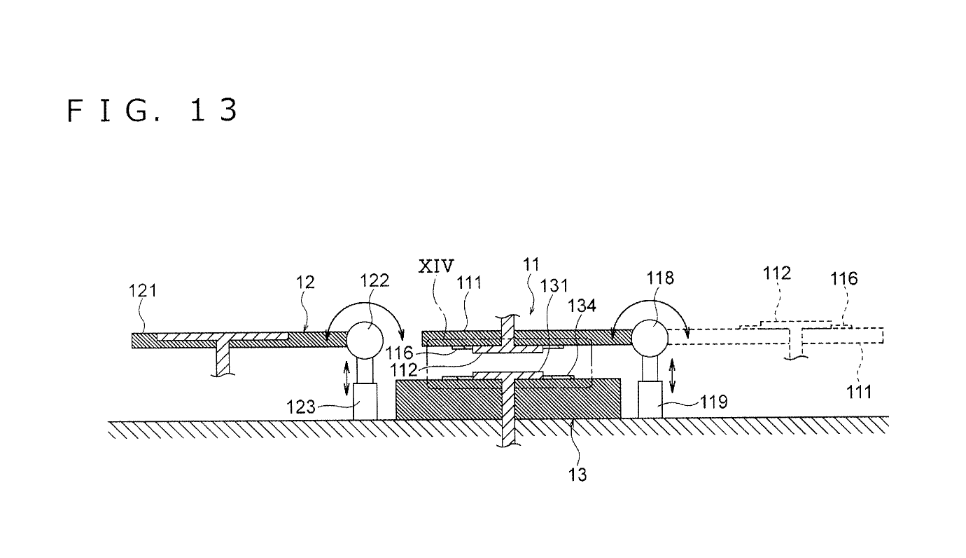

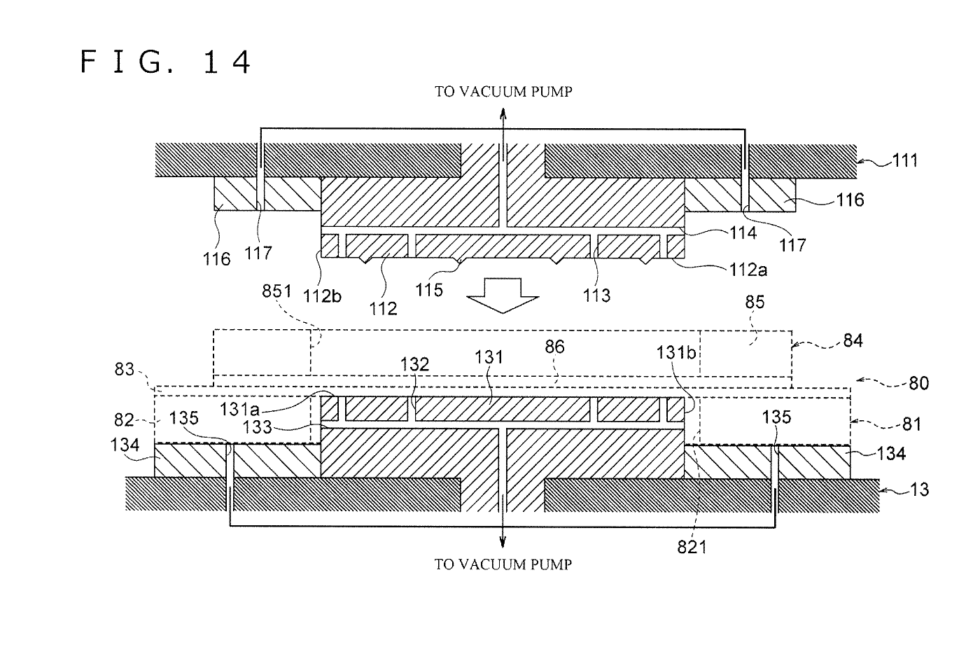

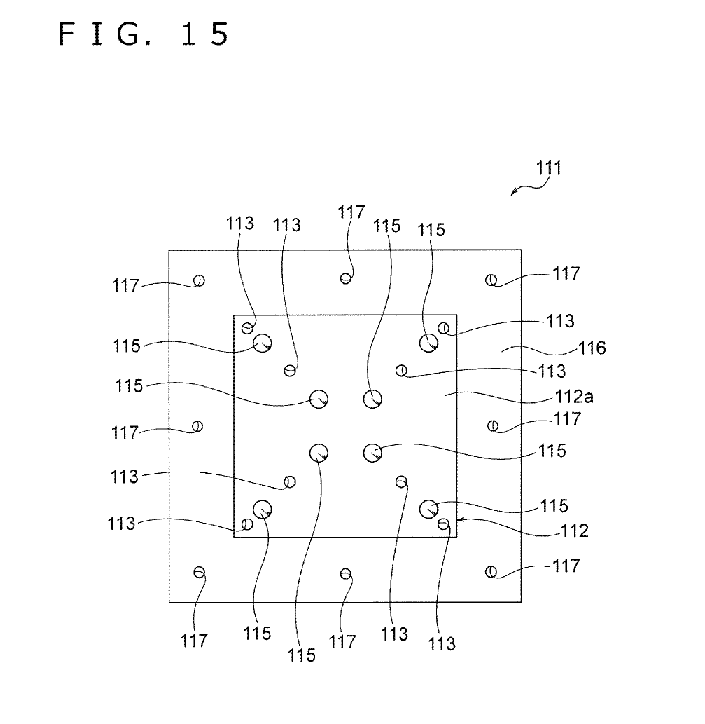

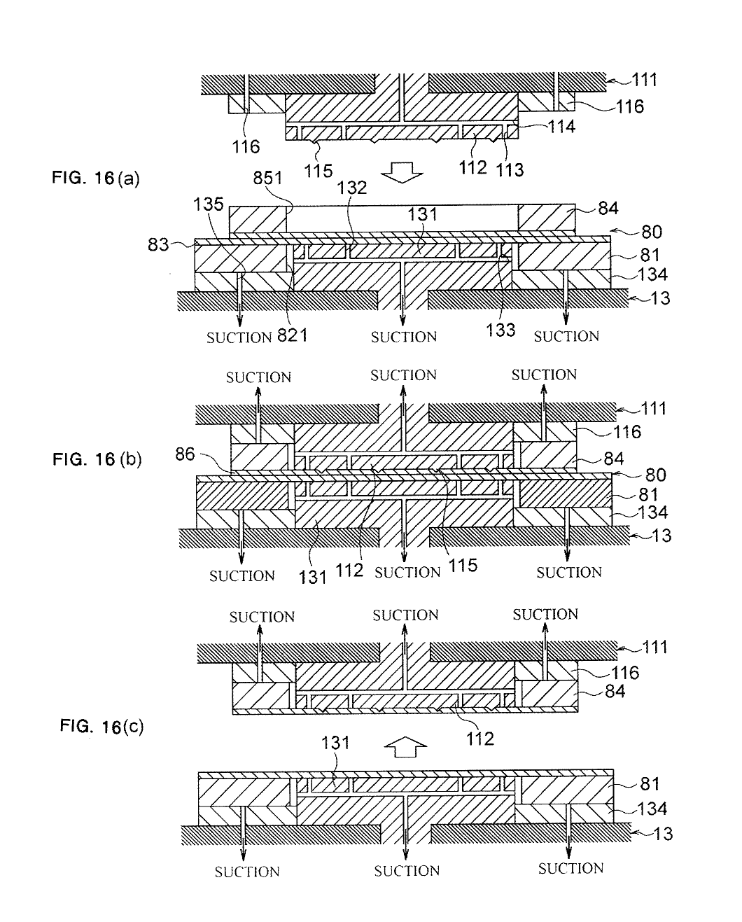

FIG. 12 is a plan view illustrating the housing unit in the present embodiment, and FIG. 13 is a cross-sectional view illustrating the housing unit. FIG. 14 is an enlarged view illustrating an XIV portion of FIG. 13. FIG. 15 is a plan view illustrating a holding portion of a first reversing arm in the present embodiment. FIGS. 16(a) to 16(c) are diagrams illustrating an empty test carrier disassembly operation of the housing unit in the present embodiment.

As illustrated in FIG. 12, the housing unit 10 in the present embodiment includes two reversing arms 11 and 12, two tables 13 and 14, and five transfer arms 15 to 19. Each of the transfer arms 15 to 19 is a transfer means which can three-dimensionally move a work (the empty test carrier 80, the cover member 84, the base member 81, the die 90, or the test carrier 80 in which the die 90 is housed). For example, a robot arm or a pick-and-place apparatus can be used as each of the transfer arms 15 to 19.

In the housing unit 10, first, the first transfer arm 15 transfers the empty test carrier 80 (that is, the test carrier 80 in which the die 90 is not housed; hereinafter, simply referred to as an “empty carrier”) from a carrier tray 50 to the disassembly table 13. Then, the empty carrier 80 is disassembled by the disassembly table 13 and the first reversing arm 11, and the cover member 84 detached from the base member 81 is reversed by the first reversing arm 11.

Although not particularly illustrated in the drawings, the carrier tray 50 includes a plurality of concave portions which are arranged in a matrix, and the empty carrier 80 can be housed in each of the concave portions. A plurality of carrier trays 50 are stacked and stored in the housing unit 10. As described above, the carrier tray 50 is supplied from the retrieving unit 30 by the return unit 40.

As illustrated in FIG. 13, the first reversing arm 11 includes: a holding portion Ill which sucks and holds the cover member 84 of the empty carrier 80; a rotating portion 118 which rotates the holding portion 111 by 180 degrees; and a lifting portion 119 which moves the holding portion 111 in the vertical direction. The rotating portion 118 can move the holding portion 111 to a position at which the holding portion 111 is opposite to the disassembly table 13 or retreat the holding portion 111 from the opposite position. The lifting portion 119 can move the holding portion 111 so as to approach or separate from the disassembly table 13.

As illustrated in FIG. 14, the holding portion 111 includes first and second suction portions 112 and 116.

The first suction portion 112 protrudes with respect to the second suction portion 116 in a concave shape in the downward direction of FIG. 14. The first suction portion 112 can be inserted into the central opening 851 of the cover frame 85 of the empty carrier 80 and can come into contact with the cover film 86. A first suction port 113 is opened in a first contact surface 112a of the first suction portion 112. A second suction port 114 is opened in a first side surface 112b of the first suction portion 112. Both the suction ports 113 and 114 are connected to a vacuum pump (not illustrated) through a passage.

In the present embodiment, the first suction portion 112 includes a plurality of protrusions 115. The protrusions 115 are provided on the first contact surface 112a so as to protrude toward the cover film 86. As illustrated in FIG. 15, the first suction ports 113 or the protrusions 115 are arranged on the diagonal lines of the first contact surface 112a. For example, the number of suction ports 113 and 114, the number of protrusions 115, or the layout thereof is not particularly limited.

The second suction portion 116 has a rectangular ring shape which surrounds the first suction portion 113 and can come into contact with the cover frame 85 of the empty carrier 80. A suction port 117 which is connected to the vacuum pump through a passage is opened in a contact surface of the second suction portion 116 which can come into contact with the cover frame 85. If the width of the cover frame 85 is not sufficiently large, the suction port 117 may not be formed in the second suction portion 116.

The second suction portion 116 is made of an elastic material with high airtightness, such as silicone rubber or chloroprene rubber. The second suction portion 116 comes into close contact with the cover frame 85 so as to seal a space in the central opening 851.

As illustrated in FIG. 13, the disassembly table 13 includes third and fourth suction portions 131 and 134 which suck and hold the base member 81 of the empty carrier 80 transferred by the first transfer arm 15.

As illustrated in FIG. 14, the third suction portion 131 protrudes upward in a convex shape with respect to the fourth suction portion 134. The third suction portion 131 can be inserted into the central opening 821 of the base frame 82 of the empty carrier 80 and can come into contact with the base film 83. A third suction port 132 is opened in a second contact surface 131a of the third suction portion 131. A fourth suction port 133 is opened in a second side surface 131b of the third suction portion 131. Both the suction ports 132 and 133 are connected to the vacuum pump (not illustrated) through a passage.

The fourth suction portion 134 has a rectangular ring shape which surrounds the third suction portion 131 and can come into contact with the base frame 82 of the empty carrier 80. A suction port 135 which is connected to the vacuum pump through a passage is opened in a contact surface of the fourth suction portion 134 which can come into contact with the base frame 82. If the width of the base frame 82 is not sufficiently large, the suction port 135 may not be formed in the fourth suction portion 134.

The fourth suction portion 134 is made of an elastic material with high airtightness, such as silicone rubber or chloroprene rubber. The fourth suction portion 134 comes into close contact with the base frame 82 so as to seal a space in the central opening 821.

When the empty carrier 80 is placed on the disassembly table 13 by the first transfer arm 15, the third suction portion 131 sucks the base film 83, and the fourth suction portion 134 sucks the base frame 82. Therefore, the disassembly table 13 sucks and holds the base member 81. At that time, the internal space of the central opening 821 of the base frame 82 is sealed by the fourth suction portion 134, and the sealed space is evacuated through the fourth suction port 133. Therefore, the base member 81 is fixedly held by the disassembly table 13.

Then, as illustrated in FIG. 16(a), in the first reversing arm 11, the holding portion 111 is moved to the empty carrier 80 by the lifting portion 119. Then, the first suction portion 112 comes into close contact with the cover film 86, and the second suction portion 116 comes into close contact with the cover frame 85.

In this state, when the vacuum pump of the first reversing arm 11 is driven, the first suction portion 112 sucks the cover film 86, and the second suction portion 116 sucks the cover frame 85, as illustrated in FIG. 16(b). Therefore, the first reversing arm 11 sucks and holds the cover member 84. At that time, the internal space of the central opening 851 of the cover frame 85 is sealed by the second suction portion 116, and the sealed space is evacuated through the second suction port 114. Therefore, the cover member 84 is fixedly held by the first reversing arm 11.

Then, when the lifting portion 119 of the first reversing arm 11 lifts the holding portion 111, the cover member 84 is detached from the base member 81, as illustrated in FIG. 16(c). At that time, in the present embodiment, since the protrusions 115 of the first suction portion 112 causes the non-uniform adhesion between the base film 83 and the cover film 86, it is possible to smoothly detach the cover member 84 from the base member 81.

Then, as illustrated in FIG. 12, in the first reversing arm 11, the rotating portion 118 rotates the holding portion 111 by 180 degrees so as to reverse the cover member 84. Then, the second transfer arm 16 transfers the cover member 84 to the assembly table 14. Suction ports which are connected to a vacuum pump through a passage are opened in the upper surface of the assembly table 14. The assembly table 14 can suck and hold the cover member 84.

Then, the third transfer arm 17 transfers the untested die 90 to the die tray 60 and places the die 90 on the cover member 84 which is sucked and held by the assembly table 14. At that time, in the present embodiment, since the cover film 86 has a self-adhesive property, it is possible to temporarily fix the die 90 to the cover film 86 only by placing the die 90 on the cover film 86. Although not particularly illustrated in the drawings, the die tray 60 includes a plurality of concave portions which are arranged in a matrix, and the die 90 can be inserted into each of the concave portions. The die trays 60 are stacked and stored in the housing unit 10.

The base member 81 from which the cover member 84 has been detached by the first reversing arm 11 and which has been held by the disassembly table 13 is held and reversed by the second reversing arm 12.

As illustrated in FIG. 13, the second reversing arm 12 includes: a holding portion 121 which sucks and holds the base member 81 of the test carrier 80; a rotating portion 122 which rotates the holding portion 121 by 180 degrees; and a lifting portion 123 which moves the holding portion 123 in the vertical direction.

A suction port is opened in a surface of the holding portion 121 which comes into contact with the base member 81. The suction port is connected to a vacuum pump through a passage. In the present embodiment, since the second reversing arm 12 does not disassemble the test carrier 80, the holding portion 121 does not have the suction portions 112 and 116 of the holding portion 111 in the first reversing arm 11. However, the invention is not limited thereto.

The rotating portion 122 can move the holding portion 121 to a position at which the holding portion 121 is opposite to the disassembly table 13 or can retreat the holding portion 121 from the opposite position. The lifting portion 123 can move the holding portion 121 so as to approach or separate from the disassembly table 13.

As illustrated in FIG. 12, the base member 81 which is reversed by the second reversing arm 12 is transferred to the assembly table 14 by the fourth transfer arm 18. The fourth transfer arm 18 places the base member 81 on the cover member 84 held by the assembly table 14. In this way, the die 90 is interposed between the base member 81 and the cover member 84, and the test carrier 80 is completed.

At that time, in the present embodiment, since the cover film 86 has a self-adhesive property, the base member 81 and the cover member 84 are stuck only by the close contacting these, and the base film 83 and the cover film 86 are integrated with each other.

In the present embodiment, the cover film 86 is more flexible than the base film 83, and the tension of the cover film 86 is increased by a value corresponding to the thickness of the die 90. The die 90 is pressed against the base film 83 by the tension of the cover film 86. Therefore, it is possible to prevent the positional deviation of the die 90.

Although not particularly illustrated in the drawings, the die 90 and the base member 81 are aligned with each other using, for example, a camera while the die 90 is being transferred by the third transfer arm 17 or while the base member 81 is being transferred by the fourth transfer arm 18.

In the present embodiment, the base member 81 and the cover member 86 are stuck to each other using the self-adhesive property of the cover film 86. However, the invention is not limited thereto. For example, the base member 81 and the cover member 84 may be stuck to each other in a decompression chamber (so-called decompression method) or they may be stuck to each other by both the self-adhesive method and the decompression method.

The test carrier 80 which has been assembled on the assembly table 14 and in which the die 90 has been housed, is transferred to the test unit 20 by the fifth transfer arm 19.

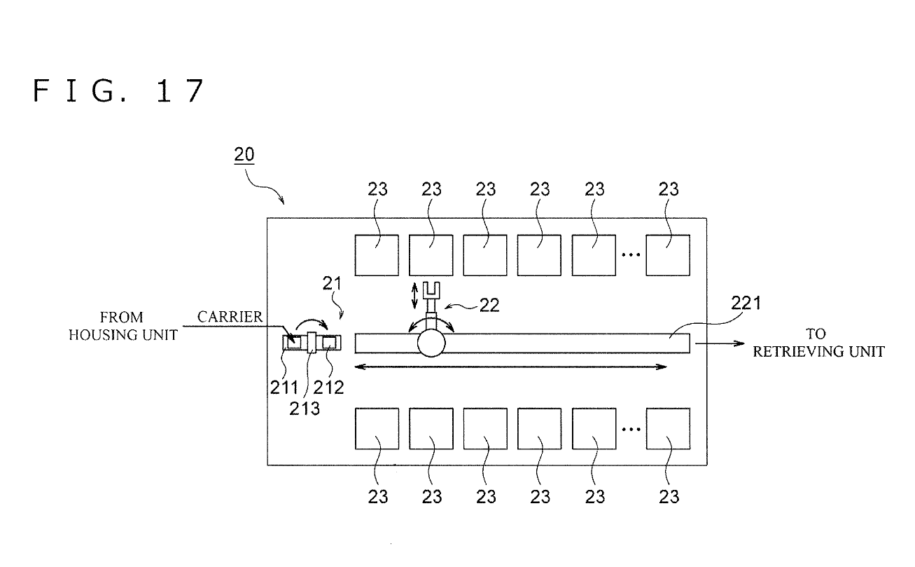

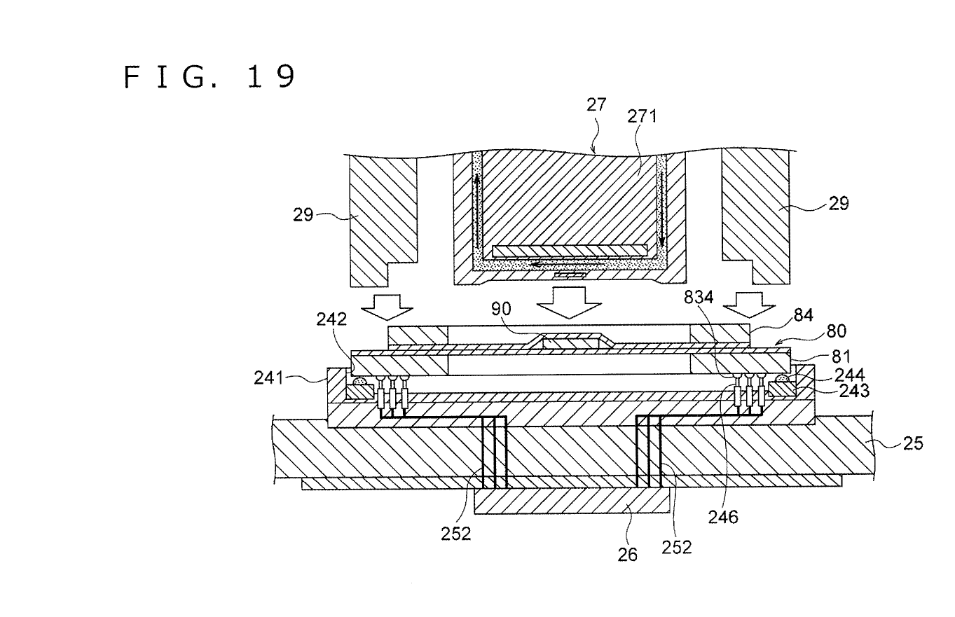

FIG. 17 is a plan view illustrating the structure of the test unit in the present embodiment. FIG. 18 is a cross-sectional view illustrating the internal structure of a test cell in the present embodiment. FIG. 19 is a cross-sectional view illustrating another example of the test cell in the present embodiment.

As illustrated in FIG. 17, the test unit 20 includes a reversing apparatus 21, a transfer arm 22, and test cells 23. The test carrier 80 supplied from the housing unit 10 is rotated 180 degrees by the reversing apparatus 21 and is then supplied to the test cell 23 by the transfer arm 22.

The reversing apparatus 21 includes: a pair of holding portions 211 and 212 which can suck and hold the test carrier 80; and a rotating portion 213 which rotates one holding portion 211 by 180 degrees with respect to the other holding portion 212. The transfer arm 22 is, for example, a robot arm which can move on a guide rail 221 and can three-dimensionally move the test carrier 80.

When the test carrier 80 is supplied to the test cell 23 by the transfer arm 22, the test cell 23 tests the die 90 which is housed in the test carrier 80. In the test unit 20, a plurality of test cells 23 are arranged in a matrix on both sides of the guide rail 221. Each of the test cells 23 can independently perform a test. For example, the number of test cells 23 or the layout thereof is not particularly limited.

As illustrated in FIG. 18, each of the test cells 23 includes a socket 24, a board 25, a test circuit 26, and a temperature adjustment head 27. The socket 24 includes a pocket 241 into which the test carrier 80 is put.

The pocket 241 includes a concave portion 242 which can accommodate the test carrier 80. A stopper 243 is provided in the entire outer circumference of the concave portion 242. A sealing member 244 is provided on the upper portion of the stopper 243. For example, a rubber packing can be used as the sealing member 244. When the outer circumference of the test carrier 80 comes into contact with the sealing member 244, the concave portion 242 is sealed.

The pocket 241 is mounted on the board 25, and a suction port 245 is opened in the bottom of the pocket 241. The suction port 245 is connected to a vacuum pump 28 through a connection path 251 formed in the board 25.

Each of contactors 246, such as a pogo pin, is provided in the concave portion 242 so as to correspond to the external terminal 834 of the test carrier 80. Each of the contactors 246 is electrically connected to the test circuit (tester chip) 26 which is mounted on the rear surface of the board 25 through a wiring pattern 252 formed in the board 25. The test circuit 26 may be mounted on the upper surface of the board 25. In this case, the test circuit 26 is arranged on the side of the pocket 241.

In the present embodiment, the tester circuit 26 is a chip with a function of testing the electronic circuit formed in the die 90 and is a one-chip tester with the functions of the tester according to the related art. The tester circuit 26 may be, for example, a multi-chip module (MCM).

As illustrated in FIG. 18, the temperature adjustment head 27 includes a block 271 which comes into contact with the cover film 86 of the test carrier 80. A temperature sensor 272 and a heater 273 are provided in the block 271, and a flow path 274 through which a coolant can flow is also formed in the block 271. The flow path 274 is connected to a chiller (not illustrated).

The block 271 of the temperature adjustment head 27 can be moved by, for example, an air cylinder or a motor with a ball screw mechanism, which is not particularly illustrated, so as to approach or separate from the test carrier 80 put into the pocket 241. The temperature sensor 272 measures the temperature of the die 90 which is being tested in the state that the block 271 of the temperature adjustment head 27 comes into contact with the cover film 86 of the test carrier 80. The temperature of the die 90 is controlled by the heater 273 and the coolant in the flow path 274 on the basis of the measurement result.

In the present embodiment, when the transfer, arm 22 puts the test carrier 80 into the pocket 241, the concave portion 242 is sealed by the base member 81 of the test carrier 80 and the sealing member 244 of the pocket 241. In this state, when the vacuum pump 28 is operated to decompress the concave portion 242, the test carrier 80 is drawn to the pocket 241, the contactor 246 comes into contact with the external terminal 834, and the tester circuit 26 tests the electronic circuit formed in the die 90. During the test, the temperature adjustment head 27 comes into contact with the test carrier 80, and the temperature of the die 90 is controlled by the heater 273 or the coolant in the flow path 274.

As illustrated in FIG. 19, instead of using the vacuum pump 28, the pressing head 29 may directly press the cover member 84 of the test carrier 80 from the upper side so as to bring the contactor 246 into contact with the external terminal 834 of the test carrier 80. The pressing head 29 can be moved by, for example, an air cylinder or a motor with a ball screw mechanism, which is not particularly illustrated, so as to approach or separate from the test carrier 80.

The above-mentioned test cell 23 can correspond to the test carrier illustrated in FIG. 6 or FIG. 7 in which the external terminal 834 protrudes downward. When the test cell 23 corresponds to the test carrier illustrated in FIGS. 2 to 5 in which the external terminal 834 protrudes upward, the contactor 246 may be provided in a lifting head which can be moved in the vertical direction, such as the pressing head 29 illustrated in FIG. 19, and may approach the external terminal 834 from the upper side, which is not particularly illustrated.

When the test for the die 90 is completed, the test carrier 80 is collected from the test cell 23 by the transfer arm 22 and is transferred to the retrieving unit 30. The test carrier 80 may be supplied to other test cells 23 before the test carrier 80 is transferred to the retrieved unit 30.

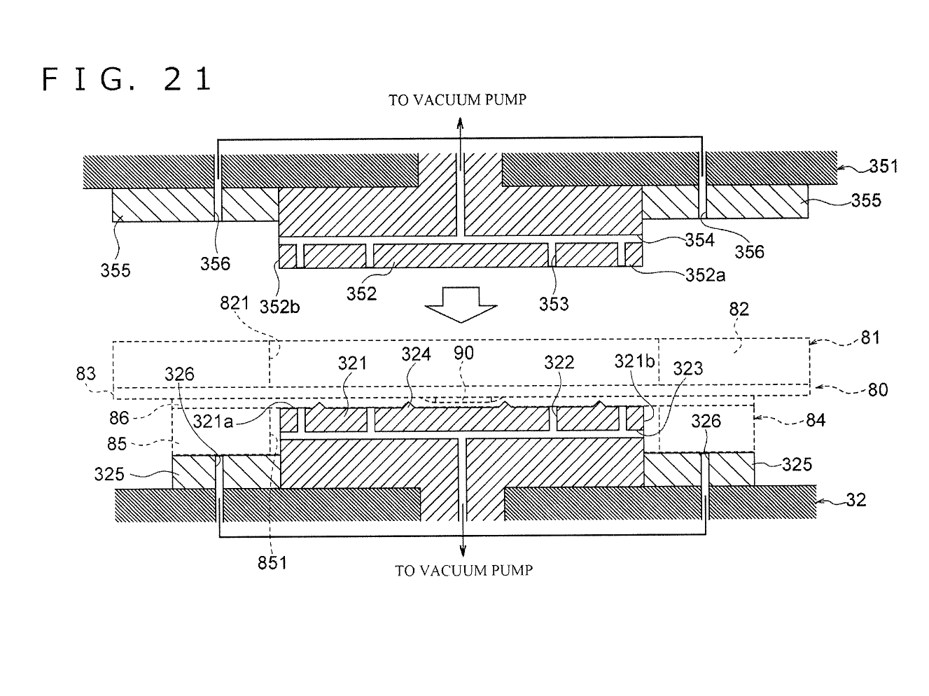

FIG. 20 is a schematic cross-sectional view illustrating the structure of the retrieving unit in the present embodiment. FIG. 21 is an enlarged view illustrating an XXI portion of FIG. 20.

As illustrated in FIG. 20, the retrieving unit 30 includes a reversing apparatus 31, a holding arm 35, and a classification arm 36. The holding arm 35 or the classification arm 36 is a transfer means which can three-dimensionally move a work (the base member 81, the empty carrier 80, or the die 90). For example, a robot arm or a pick-and-place apparatus can be used as the arms 35 and 36. The structure of a holding portion 351 of the holding arm 35 will be described in detail below.

In the retrieving unit 30, first, the reversing apparatus 31 reverses the test carrier 80 supplied by the transfer arm 22 of the test unit 20.

The reversing apparatus 31 includes: a first holding portion 32 which sucks and holds the cover member 84 of the test carrier 80; a second holding portion 33 which sucks and holds the base member 81 of the test carrier 80; and a rotating portion 34 which can rotate the second holding portion 33 by 180 degrees.

As illustrated in FIG. 21, the first holding portion 32 includes first and second suction portions 321 and 325, similarly to the holding portion 111 of the first reversing arm 11.

The first suction portion 321 protrudes upward with respect to the second suction portion 325. The first suction portion 321 can be inserted into the central opening 851 of the cover frame 85 in the test carrier 80 and can come into contact with the cover film 86. A first suction port 322 is opened in a first contact surface 321a of the first suction portion 321. A second suction port 323 is opened in a first side surface 321b of the first suction portion 321. Both the suction ports 322 and 323 are connected to a vacuum pump (not illustrated) through a passage.

In addition, in the present embodiment, the first suction portion 321 includes a plurality of protrusions 324. The protrusions 324 are provided on the first contact surface 321a so as to protrude toward the cover film 86. Although not particularly illustrated in the drawings, similarly to the protrusions 115 of the first reversing arm 11, the protrusions 324 are arranged on the diagonal lines of the first contact surface 321a so as not to overlap the die 90.

The second suction portion 325 has a rectangular ring shape which surrounds the first suction portion 321 and can come into contact with the cover frame 85 of the test carrier 80. A suction port 326 which is connected to a vacuum pump through a passage is opened in a contact surface of the second suction portion 325 which can come into contact with the cover frame 85. If the width of the cover frame 85 is not sufficiently large, the suction port 326 may not be formed in the second suction portion 325.

The second suction portion 325 is made of an elastic material with high airtightness, such as silicone rubber or chloroprene rubber. The second suction portion 325 comes into close contact with the cover frame 85 so as to seal a space in the central opening 851.

The second holding portion 33 has the same structure as the above-mentioned holding portion 121 of the second reversing arm 12. A suction port is opened in a surface of the second holding portion 33 which comes into contact with the base member 81 of the test carrier 80.

When the test carrier 80 is placed on the second holding portion 33 by the transfer arm 22 of the test unit 20, the rotating portion 34 reverses the second holding portion 33 and places the test carrier 80 on the first holding portion 32 in the state that the test carrier 80 is sucked and held by the second holding portion 33. Then, the first holding portion 32 sucks and holds the test carrier 80, and second holding portion 33 releases the suction. Then, the rotating portion 34 rotates the second holding portion 33 again. Therefore, the test carrier 80 is transferred from the second holding portion 33 to the first holding portion 32. When the first holding portion 32 sucks and holds the test carrier 80, the test carrier 80 is disassembled by the first holding portion 32 and the holding arm 35.

As illustrated in FIG. 21, the holding portion 351 of the holding arm 35 includes third and fourth suction portions 352 and 355 which suck and hold the base member 81 of the test carrier 80, similarly to the disassembly table 13.

As illustrated in FIG. 21, the third suction portion 352 protrudes downward in a convex shape with respect to the fourth suction portion 355. The third suction portion 352 can be inserted into the central opening 821 of the base frame 82 of the test carrier 80 and can come into contact with the base film 83. A third suction port 353 is opened in a second contact surface 352a of the third suction portion 352. A fourth suction port 354 is opened in a second side surface 352b of the third suction portion 352. Both the suction ports 353 and 354 are connected to a vacuum pump (not illustrated) through a passage.

The fourth suction portion 355 has a rectangular ring shape which surrounds the third suction portion 352 and can come into contact with the base frame 82 of the test carrier 80. A suction port 356 which is connected to the vacuum pump through a passage is opened in a contact surface of the fourth suction portion 355 which can come into contact with the base frame 82. If the width of the base frame 82 is not sufficiently large, the suction port 356 may not be formed in the fourth suction portion 355.

The fourth suction portion 325 is made of an elastic material with high airtightness, such as silicone rubber or chloroprene rubber. The fourth suction portion 352 comes into close contact with the base frame 82 so as to seal a space in the central opening 821.

When the test carrier 80 is sucked and held by the first holding portion 32, the holding arm 35 approaches the test carrier 80 and sucks and holds the cover member 84. Then, the holding arm 35 is lifted so as to detach the base member 81 from the cover member 84.

At that time, in the present embodiment, since the protrusions 324 of the first suction portion 321 causes the non-uniform adhesion between the base film 83 and the cover film 86, it is possible to smoothly detach the base member 81 from the cover member 84.

In the present embodiment, since the second suction portion 325 is formed of a sealing member, a space in the central opening 851 of the cover frame 85 is sealed. Since the sealed space is evacuated through the second suction port 323, the cover member 84 is fixedly held by the first holding portion 32. Similarly, since the fourth suction portion 355 is formed of a sealing member, a space in the central opening 821 of the base frame 82 is sealed. Since the sealed space is evacuated through the second suction port 354, the base member 81 is fixedly held by the holding arm 35. Therefore, it is possible to easily detach the base member 81 from the cover member 84.

When the base member 81 is detached from the cover member 84, the holding arm 35 further lifts the base member 81 and waits in this state. In this state, the classification arm 36 picks up the die 90 from the cover member 84 and transfers the die 90 to the die tray 61 corresponding to the test result. The retrieving unit 30 is provided with a plurality of die trays 61 corresponding to each test category. The classification arm 36 transfers the die 90 to the die tray 61 corresponding to the test result so as to classify the die 90.

The holding arm 35 places the base member 81 on the cover member 84 from which the die 90 has been detached, and the base member 81 is stuck to the cover member 84 again so as to assemble the empty carrier 80. At that time, in the present embodiment, since the cover film 86 has a self-adhesive property, the base member 81 and the cover member 84 are stuck only by the close contacting these, and the base film 83 and the cover film 86 are integrated with each other.

Then, the holding arm 35 is lifted once, and the reversing apparatus 31 reverses the empty carrier 80. Then, the holding arm 35 picks up the test carrier 80 from the second holding portion 33 and transfers the test carrier 80 to the carrier tray 51 provided in the retrieving unit 30. As described above, the carrier tray 51 is transferred from the retrieving unit 30 to the housing unit 10 by the return unit 40 and is recycled.

As described above, in the present embodiment, since the base member 81 and the cover member 84 are constantly stuck to each other except when the die 90 is housed and retrieved, it is possible to protect the bump 833 on the base film 83 and to prevent a foreign material, such as dust, from being infiltrated into the accommodation space 87 of the test carrier 80.

The above-mentioned embodiment has been described for ease of understanding of the invention and does not limit the invention. Therefore, each component described in the embodiment includes all changes in the design or equivalents in the technical scope of the invention.

### EXPLANATIONS OF LETTERS OR NUMERALS

1 ELECTRONIC DEVICE TESTING APPARATUS
10 HOUSING UNIT
11 FIRST REVERSING ARM
111 HOLDING PORTION
112 FIRST SUCTION PORTION
112a FIRST CONTRACT SURFACE
112b FIRST SIDE SURFACE
113 FIRST SUCTION PORT
114 SECOND SUCTION PORT
115 PROTRUSION
116 SECOND SUCTION PORTION
117 SUCTION PORT
12 SECOND REVERSING ARM
13 DISASSEMBLY TABLE
131 THIRD SUCTION PORTION
131a SECOND CONTRACT SURFACE
131b SECOND SIDE SURFACE
132 THIRD SUCTION PORT
133 FOURTH SUCTION PORT
134 FOURTH SUCTION PORTION
135 SUCTION PORT
14 ASSEMBLY TABLE
15 TO 19 FIRST TO FIFTH TRANSFER ARMS
20 TEST UNIT
21 REVERSING APPARATUS
22 TRANSFER ARM
23 TEST CELL
30 RETRIEVING UNIT
31 REVERSING APPARATUS
32 FIRST HOLDING PORTION
321 FIRST SUCTION PORTION
321a FIRST CONTRACT SURFACE
321b FIRST SIDE SURFACE
322 FIRST SUCTION PORT
323 SECOND SUCTION PORT
324 PROTRUSION
325 SECOND SUCTION PORTION
326 SUCTION PORT
33 SECOND HOLDING PORTION
34 ROTATING PORTION
35 HOLDING ARM
351 HOLDING PORTION
352 THIRD SUCTION PORTION
352a SECOND CONTRACT SURFACE
352b SECOND SIDE SURFACE
353 THIRD SUCTION PORT
354 FOURTH SUCTION PORT
355 FOURTH SUCTION PORTION
356 SUCTION PORT
36 CLASSIFICATION ARM
40 RETURN UNIT
80 TEST CARRIER
81 BASE MEMBER
82 BASE FRAME
821 CENTRAL OPENING
83 BASE FILM
84 COVER MEMBER
85 COVER FRAME
851 CENTRAL OPENING
86 COVER FILM
87 ACCOMMODATION SPACE
90 DIE

1. A carrier disassembling apparatus configured to disassemble a test carrier including a first member and a second member which come into contact with each other, the carrier disassembling apparatus comprising:
a first holder configured to suck and hold the first member; and
a second holder configured to suck and hold the second member, wherein
one of the first holder or the second holder can relatively approach and separate from the other of the second holder or the first holder,
the first holder includes a first contract surface which comes into contact with the first member, and
the first contract surface includes a protrusion which protrudes toward the first member.

2. The carrier disassembling apparatus according to claim 1, wherein
the first member includes:
a first frame member which has a frame shape with a first opening; and
a first film member which is stuck to the first frame member,
the first holder includes:
a first suction portion which is inserted into the first opening and sucks the first film member; and
a second suction portion which sucks the first frame member,
the first suction portion includes the first contract surface which comes into contact with the first film member, and
a first suction port is opened in the first contract surface.

3. The carrier disassembling apparatus according to claim 2, wherein
the first suction portion includes a first side surface which intersects the first contract surface, and
a second suction port is opened in the first side surface.

4. The carrier disassembling apparatus according to claim 2, wherein
the second suction portion includes a first endless sealing member which comes into contact with the first frame member.

5. The carrier disassembling apparatus according to claim 2, wherein
the first film member has a self-adhesive property.

6. The carrier disassembling apparatus according to claim 5, wherein
the first film member is made of silicone rubber.

7. The carrier disassembling apparatus according to claim 1, wherein
the second member includes:
a second frame member which has a frame shape with a second opening; and
a second film member which is stuck to the second frame member,
the second holder includes:
a third suction portion which is inserted into the second opening and sucks the second film member; and
a fourth suction portion which sucks the second frame member,
the third suction portion includes a second contract surface which comes into contact with the second film member, and
a third suction port is opened in the second contract surface.

8. The carrier disassembling apparatus according to claim 7, wherein
the third suction portion includes a second side surface which intersects the second contract surface, and
a fourth suction port is opened in the second side surface.

9. The carrier disassembling apparatus according to claim 8, wherein
the fourth suction portion includes a second endless sealing member which comes into contact with the second frame member.

10. An electronic device housing apparatus configured to interpose an electronic device between a first member and a second member to house the electronic device in a test carrier, the electronic device housing apparatus comprising:
the first carrier disassembly apparatus according to claim 1 configured to disassemble an empty test carrier; and
a first carrier assembly apparatus configured to interpose the electronic device between the first member and the second member and stick the first member and the second member.

11. An electronic device retrieving apparatus configured to retrieve an electronic device between a first member and a second member of a test carrier, the electronic device retrieving apparatus comprising:
the second carrier disassembly apparatus according to claim 1 configured to disassemble the test carrier; and
a second carrier assembly apparatus configured to stick the disassembled first and second members to reassemble the test carrier, wherein
the second carrier disassembly apparatus further includes an retrieving device configured to retrieve the electronic device from the disassembled test carrier.

12. An electronic device testing apparatus configured to house an electronic device in a test carrier and test the electronic device, the electronic device testing apparatus comprising:
an electronic device housing unit configured to interpose an electronic device between a first member and a second member to house the electronic device in a test carrier, the electronic device housing unit comprising:
the first carrier disassembly apparatus according to claim 1 configured to disassemble an empty test carrier; and
a first carrier assembly apparatus configured to interpose the electronic device between the first member and the second member and stick the first member and the second member;
a test unit configured to test the electronic device housed in the test carrier; and
an electronic device retrieving unit configured to retrieve an electronic device between a first member and a second member of a test carrier, the electronic device retrieving unit comprising:
the second carrier disassembly apparatus according to claim 1 configured to disassemble the test carrier; and
a second carrier assembly apparatus configured to stick the disassembled first and second members to reassemble the test carrier, wherein
the second carrier disassembly apparatus further includes an retrieving device configured to retrieve the electronic device from the disassembled test carrier.
